(19) United States
(12) Patent Application Publication
(10) Pub. No.: US 2018/0136762 A1
(43) Pub. Date: May 17, 2018

(54) FLEXIBLE DISPLAY DEVICE HAVING INTEGRATED SENSOR AND METHOD OF MANUFACTURING THE SAME

(71) Applicant: Samsung Display Co., Ltd., Yongin-si (KR)

(72) Inventors: Seung Heui JEONG, Cheonan-si (KR); Kwanghyeok Kim, Cheonan-si (KR); Sungbae Park, Busan (KR); Sangyoon Lee, Pohang-si (KR); Jeongwon Lee, Incheon (KR)

(21) Appl. No.: 15/416,527

(22) Filed: Jan. 26, 2017

(30) Foreign Application Priority Data
Nov. 16, 2016 (KR) 10-2016-0152342

(51) Int. Cl. G06F 3/046; H01L 51/00; H01L 27/32; G02F 1/1333; G06F 3/044; G06F 3/041

(52) U.S. Cl. CPC G06F 3/046; H01L 51/0097; H01L 27/323; G02F 1/13338; G02F 1/1368; G06F 3/044; G06F 3/0416; G06F 3/0414; G02F 1/133305

(57) ABSTRACT

A display device may include: a substrate having a first and second sides; display elements disposed on the first side of the substrate configured to display image; a first sensor disposed on the second side of the substrate to sense a first input; and a second sensor disposed on the first sensor to sense a second input, the second sensor having a layer integrated with the first sensor.

### CROSS-REFERENCE TO RELATED APPLICATION

This application claims priority from and the benefit of Korean Patent Application No. 10-2016-0152342, filed on Nov. 16, 2016, which is hereby incorporated by reference for all purposes as if fully set forth herein.

### BACKGROUND

### Field

The invention relates generally to display devices, more specifically, to a flexible display device including an integrated sensor.

### Discussion of the Background

Liquid Crystal Display (LCD) and organic light emitting diode (OLED) displays are widely used in mobile devices such as cell phones and tablet computers. Recently, consumers demand has been trending toward flexible display devices allowing the displays to be formed on a curved surface or even folded.

Also, touch screen panels are more widely used as an input device for the mobile devices. The touch screen panel may refer to an input device that may receive a user's input by sensing, for example, the user's finger or stylus touching certain area of the display device displaying an image.

The touch screen panel may detect touch on a screen using various methods including a resistive layer, photoelectric effect, piezo-electric effect, and capacitance detection, and a capacitive touch screen panel configured to detect change of capacitance caused by a touch. Such a touch screen panel may generally be disposed on front of the display panels such as liquid crystal display LCD and organic light emitting diode OLED display.

Recently, digitizers have been attached to the display device so that more detailed and fine touch operations may be achieved using a stylus pen. A digitizer may generally include EMR sensor panel configured to operate with the stylus pen, and the EMR sensor panel may be disposed on the back of the display panels.

However, by including both the touch screen panel and the EMR sensor panel on the display panel, the manufacturing cost of the display device is increased, and the total thickness of the display device increased, which may decrease the flexibility of the display device, as well as consumer demand. Also, by attaching the touch screen in front of the display panel, the display panel of the flexible display device may not be sufficiently protected from environmental factors such as external forced.

The above information disclosed in this Background section is only for enhancement of understanding of the background of the inventive concepts, and, therefore, it may contain information that does not form the prior art that is already known in this country to a person of ordinary skill in the art.

### SUMMARY

Flexible display devices including integrated sensors constructed according to the principles of the invention and methods of making the same avoid one or more of the problems and/or drawbacks of conventional devices by providing for a thinner, more robust flexible display device than heretofore practical.

Additional aspects will be set forth in the detailed description which follows, and, in part, will be apparent from the disclosure, or may be learned by practice of the inventive concept.

According to an exemplary embodiment of the invention, a display device may include: a substrate having a first and second sides; display elements disposed on the first side of the substrate configured to display image; a first sensor disposed on the second side of the substrate to sense a first input; and a second sensor disposed on the first sensor to sense a second input, the second sensor having a layer integrated with the first sensor.

The substrate may include: a support substrate; and a flexible substrate disposed between the support substrate and the display elements.

The second sensor may be configured to detect changes in an external condition of the display device.

The external condition may be a pressure applied to the display device.

The layer of the second sensor may include a first electrode layer, and wherein the second sensor further includes: a second electrode layer; and an elastic substrate disposed between the first electrode layer and the second electrode layer.

The first electrode layer may be a transmitting electrode configured to transmit scan signals.

The second electrode layer of the second sensor may be configured detect a location of the applied pressure by detecting the change of capacitance in response to the change of the gap between the first electrode layer and the second electrode layer.

The first sensor may be integrated with the support substrate.

The first input may be a location of an input device.

The first sensor may be an electromagnetic resonance (EMR) sensor.

The input device may include a resonance circuit to generate a resonance frequency signal in response to an electromagnetic field generated by the EMR sensor, and wherein the EMR sensor detects the location of the input device by detecting the resonance frequency signal.

According to another exemplary embodiment of the invention, a display device may include: a substrate having first and second sides; display elements disposed on the first side of the substrate configured to display image; an electromagnetic resonance (EMR) sensor disposed on the second side of the substrate; and a pressure sensor disposed on the EMR sensor, the pressure sensor including a first electrode layer integrated with the EMR sensor.

The substrate may include: a support substrate; and a flexible substrate disposed between the support substrate and the display elements.

The pressure sensor may further include a second electrode layer and an elastic substrate disposed between the first electrode layer and the second electrode layer.

The elastic substrate may include a base substrate and an elastic layer.

The elastic layer may include an adhesive surface, and the adhesive surface of the elastic layer may be directly attached to the first electrode layer.

The flexible substrate, the support substrate, and the base substrates may be made of substantially the same material.

The flexible substrate, the support substrate, and the base substrates may each include polyimide material.

The first electrode layer may be a transmitting electrode configured to transmit scan signals, and wherein the second electrode layer of the pressure sensor may be configured to detect the change of capacitance in response to the change in the size of the gap between the first electrode layer and the second electrode layer may be configured to detect a location of a pressure applied to the display device.

According to yet another exemplary embodiment of the invention, a method of manufacturing a flexible display device having multiple sensors may include: disposing display elements configured to display image on a first surface of a substrate; forming a first sensor on a second surface of the substrate; forming a first layer of a pressure sensor on the first sensor; and attaching a second layer of the pressure sensor to the first layer of the pressure sensor.

The substrate may include: a support substrate having a first surface and a second surface; a flexible substrate having a first surface and a second surface, the flexible substrate being disposed between the support substrate and the display elements, wherein the first surface of the substrate may be the first surface of the flexible substrate, and wherein the second surface of the substrate may be the second surface of the support substrate.

The forming the first sensor may include: forming a first layer of the first sensor directly on the second surface of the support substrate; and attaching the first surface of the support substrate to the second surface of the flexible substrate.

The forming the first layer of the pressure sensor may include: forming a first electrode layer directly on the first sensor.

The attaching the second layer of the pressure sensor may include: forming a second electrode layer on an elastic substrate, the elastic substrate including an elastic layer disposed on a first surface of a base substrate; and attaching the elastic substrate to the first layer of the pressure sensor.

The second electrode layer may be disposed on a second surface of the base substrate and the elastic layer may be disposed on a first surface of the base substrate.

According to a further exemplary embodiment of the invention, an integrated sensor in a display device may include: a first sensor to detect a first condition of the display device; a second sensor to detect a second condition of the display device, and wherein the first sensor and the second sensor may be integrated without adhesive.

A layer of the second sensor may be formed directly on the first sensor.

The second condition of the display device may be the amount of pressure applied to the display device.

The layer of the second sensor may include a first electrode layer, and wherein the second sensor further includes: a second electrode layer; and an elastic substrate disposed between the first electrode layer and the second electrode layer.

The first electrode layer may be a transmitting electrode configure to transmit scan signals, and wherein the second electrode layer of the second sensor may be configured detect a location of the applied pressure by detecting the change of capacitance in response to the change in the size of a gap between the first electrode layer and the second electrode layer.

The first sensor may be directly formed on the display device without any intervening layers.

The first condition may be a location of an input device.

The first sensor may be an electromagnetic resonance (EMR) sensor.

The EMR sensor may be configured to generate an electromagnetic field and detect the location of the input device by detecting a resonance frequency signal generated by the input device in response to the electromagnetic field generated by the EMR sensor.

The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a plan view drawing illustrating a flexible display device, constructed according to the principles of the invention.

FIG. 2 is a partial, cross-sectional view of the flexible display device of FIG. 1.

FIG. 3 is a cross-sectional drawing illustrating a stacked structure of a integrated sensor constructed according to the principles of the invention.

FIG. 4 is an exploded perspective drawing illustrating a stacked structure of a integrated sensor constructed according to an exemplary embodiment of the invention.

FIG. 5 is a plan view of an exemplary embodiment of an EMR sensor of the integrated sensor of FIG. 4.

FIG. 6 is a plan view of an exemplary embodiment of a pressure sensor of the integrated sensor of FIG. 4.

FIG. 7 illustrates an exemplary operation of the pressure sensor of FIG. 6, according to an exemplary embodiment.

FIG. 8 is a cross-sectional drawing illustrating a stacked structure of a integrated sensor, according to another exemplary embodiment.

FIG. 9 is a flow chart schematically depicting some of the steps of an exemplary method of manufacturing a flexible display device including an integrated sensor constructed according to an exemplary embodiment of the invention.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to plan and/or sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have round or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

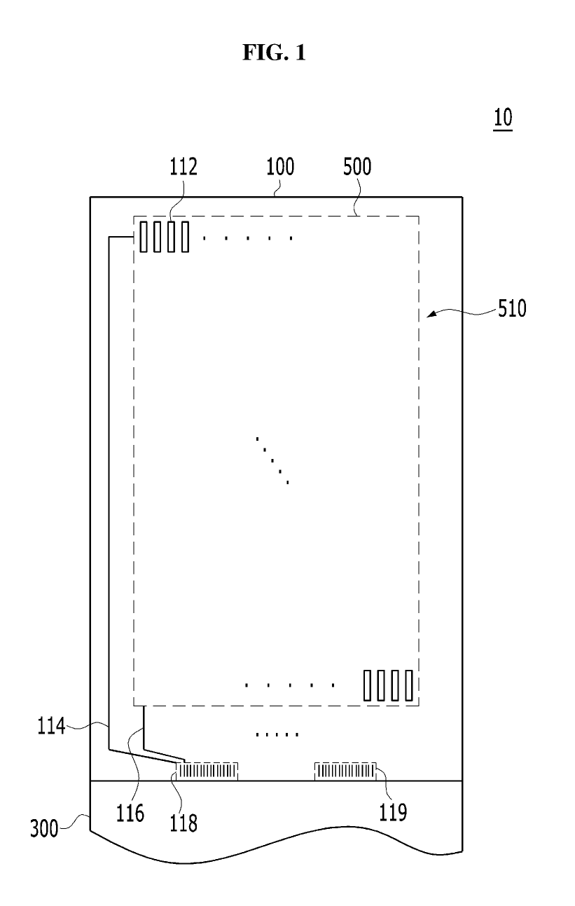

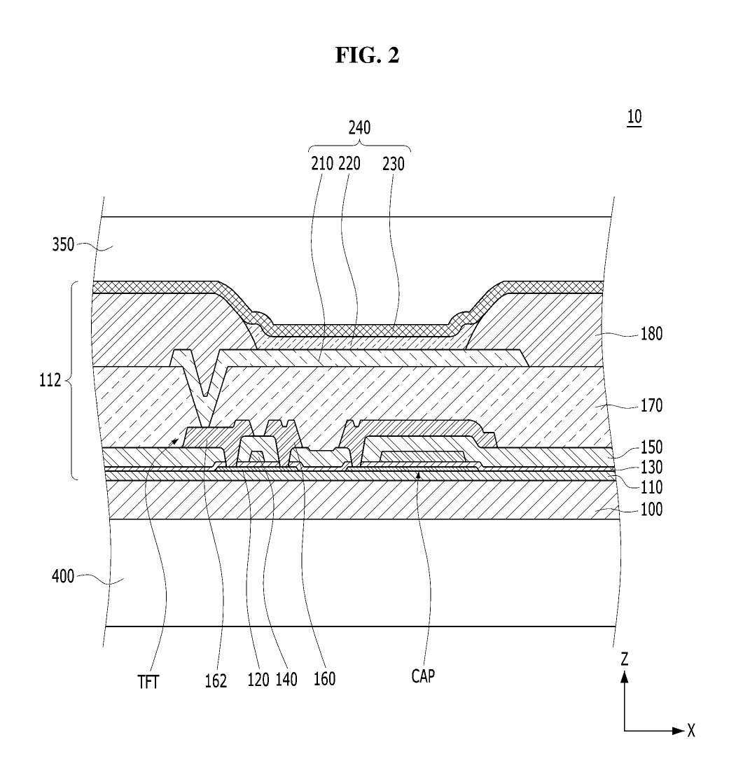

FIG. 1 is a plan view drawing illustrating a flexible display device 10 constructed according to the principles of the invention. FIG. 2 is a partial, cross-sectional view of the flexible display device 10 of FIG. 1.

According to the exemplary embodiments illustrated in FIG. 1, a integrated sensor (400, referring to FIG. 2) including an Electromagnetic Resonance (EMR) sensor and pressure sensor is incorporated into a flexible display device 10. The flexible display device 10 may include a liquid crystal display (LCD) and organic light emitting diode (OLED) display. More specifically, the flexible display device 10 may include the OLED display.

For descriptive purpose, the flexible display device including OLED display will be described hereafter. However, the exemplary embodiments are not necessarily limited thereto, and therefore, the flexible display device according to the exemplary embodiment may include various types of display.

Referring to FIG. 1, the flexible display device 10 according to the exemplary embodiment includes a flexible substrate 100 which includes a display area 500, and a plurality of pixels 112 are formed in the display area 500 of the flexible substrate 100. The flexible substrate 100 and the plurality of pixels 112 disposed on the flexible substrate 100 may be sealed by disposing an Encapsulation layer (350, referring to FIG. 2) or an encapsulation substrate. For example, the display device including a encapsulation substrate may also include sealant disposed at outer edges of the non-display area 510 which is disposed surrounding the display area 500 and between the flexible substrate 100, to seal the flexible substrate 100 and the plurality of pixels 112 disposed on the flexible substrate 100.

The encapsulating layer 350 may have a multi-layer structure. More specifically, the encapsulating layer 350 may include one or more first inorganic layers and one or more second inorganic layers, the one or more first inorganic layers and the one or more second inorganic layers are preferably alternatively stacked on one another. The one or more first inorganic layers and the one or more second inorganic layers may be respectively include inorganic materials such as silicon oxide (SiO_{X}), silicon nitride (SiN_{X}), and silicon oxynitride (SiN_{X}O_{Y}).

Also, an integrated sensor (referring to FIG. 2, 400) including a EMR sensor and a pressure sensor is disposed on a surface of the flexible substrate 100 opposite to a surface that the plurality of pixels 112 is disposed, e.g., a lower surface. Accordingly, the integrated sensor 400 may be disposed directly on the lower surface of the flexible substrate 100, and a sensing area in which the integrated sensor 400 is disposed overlaps the display area 500 in which the plurality of pixels 112 is disposed.

A plurality of signal lines 114 and 116 is connected to the plurality of pixels 112 disposed on the flexible substrate 100 of the display area 500. The plurality of signal lines 114 and 116 extend to the non-display area 510.

FIG. 1 illustrates that the plurality of signal lines include signal lines 114 and data lines 116, but the exemplary embodiment are not limited thereto, and the plurality of signal lines may further include emission line configured to control emission of OLED included in each of the plurality of pixels 112.

According to the exemplary embodiments, the plurality of pixels 112 may include a OLED and a plurality of transistors, and at least on capacitor.

Referring to FIG. 1, the plurality of signal lines 114 and 116 may be electrically connected to a driving signal pad 118 which is disposed at one side of the non-display area 510 of the flexible substrate 100 and the plurality of signal lines 114 and 116 may receive corresponding signals from the IC disposed on a Flexible Printed Circuit Board (FPCB) 300.

A sensor signal pad 119 may be disposed adjacent to the driving signal pad 118, and the sensor signal pad 119 may be electrically connected to the integrated sensor 400.

For example, the integrated sensor 400 disposed on a surface of the flexible substrate 100 may have a stacked structure including the EMR sensor and the pressure sensor stacked. The EMR sensor may include first loop coils and second loop coils, and the pressure sensor may include first electrodes and second electrodes. Here, signal lines electrically connected to the first loop coils and the second loop coils of the EMR sensor may be electrically connected to the sensor signal pad 119 through contact holes formed on the flexible substrate 100. Also, signal lines electrically connected to the first electrodes and the second electrodes of the pressure sensor may be electrically connected to the sensor signal pad 119 through contact holes formed on the flexible substrate 100.

Accordingly, the driving signal pad 118 and sensor signal pad 119 disposed at on side of the non-display area 510 of the flexible substrate 100 may be electrically connected to the Flexible Printed Circuit Board (FPCB) 300.

The FPCB 300 may include a driving IC configured to drive the plurality of pixels 112 disposed in the display area 500 of the flexible substrate 100, and a sensing IC configured to control the operation of the integrated sensor 400 disposed on one surface of the flexible substrate 100. Here, the driving IC and the sensing IC may be formed as separate ICs, or may be consolidated as a single IC.

According to the exemplary embodiment, by using a consolidated FPCB 300, the processes of bonding the FPCB and inspecting the FPCB may be simplified, and difficulty and cost of manufacturing may be reduced.

However, the exemplary embodiments are not limited thereto, and the driving signal pad 118 and the sensor signal pad 119 may be formed on a different substrate or a different layer.

Referring to FIG. 2, the flexible display device 10 includes a flexible substrate 100, a plurality of pixels 112 disposed on the flexible substrate 100, and an encapsulating layer disposed on the plurality of pixels 121.

The flexible substrate 100 may be a flat and flexible substrate having a first thickness d₁. For example, the first thickness d₁ of the flexible structure 100 may be between 5 μm and 30 μm, more particularly, substantially 10 μm.

The flexible substrate 100 may include a material with heat resistance, durability, and flexibility. For exemplary, the flexible substrate 100 may including a plastic such as a Polyethylenterephthalate PET, Polyethylennaphthalate PEN, Polyimide PI, etc., and according to the exemplary embodiment, for descriptive purpose, the flexible substrate 100 including the polyimide PI will be described hereafter.

The plurality of pixels 112 is disposed on the flexible substrate 100, each of the plurality of pixels 112 includes a thin film transistor TFT, a capacitor CAP, and an organic light emitting diode 240 electrically connected to the thin film transistor TFT. The thin film transistor TFT includes a semiconductor layer 120, a gate electrode 140, a source electrode 160, and a drain electrode 162. The semiconductor layer 120 may include at least one of polycrystalline silicon, amorphous silicon, and an organic semiconductor material. Referring to FIG. 2, the pixel may have following structure including stacked layers.

A buffer layer 110 including a silicon oxide SiOₓ or silicon nitride SiNₓ may be disposed on the flexible substrate 100 to planarize the upper surface of the flexible substrate 100 or to protect the semiconductor layer 120 of the thin film transistor TFT from impurities, and the semiconductor layer 120 may be disposed on the buffer layer 110. The gate electrode is disposed on the semiconductor layer 120, and the source electrode 162 and the drain electrode 162 may be electrically connected in response to a scan signal applied to the gate electrode 162. A gate insulation layer 130 may be disposed between the semiconductor layer 120 and the gate electrode 140 to electrical insulates the semiconductor 120 and the gate electrode 140. The gate insulating layer 130 may include silicon oxide and/or silicon nitride. An interlayer insulating layer 150 may be disposed on the gate electrode 140, and the interlayer insulating layer 150 may include at least one layer including silicon oxide and silicon nitride. The source electrode 160 and the drain electrode 162 are disposed on the interlayer insulating layer 150. The source electrode 160 and the drain electrode 162 may be electrically connected to the semiconductor layer 120 through contact holes formed in the interlayer insulating layer 150 and gate insulating layer 130.

A first insulating layer 170 may be disposed on the thin film transistor TFT, and the first insulating layer 170 may function as a protection layer and a planarization layer. More specifically, the first insulating layer 170 may planarize an upper surface of the thin film transistor TFT so that the OLED 240 may be disposed on the thin film transistor TFT, and may protect the thin film transistor TFT and other elements underneath. The first insulating layer 170 may include such as acrylic organic material or Benzocyclobutene BCB. A second insulating layer 180 may be disposed on the first insulating layer 170. The second insulating layer 180 may be a pixel define layer configured to define pixel area of each of the plurality of pixels 112, and may include organic insulating material.

The OLED 240 may be disposed on the second insulating layer 180. The OLED 240 may include a pixel electrode 210, an intermediate layer 220 including an emission layer EML, and a counter electrode 230. The pixel electrode 210 may be electrically connected to the thin film transistor TFT, and may include translucent electrode or reflective electrode. The intermediate layer 220 may be disposed in the pixel area defined by the second insulating layer 180. The intermediate layer 220 may include an emission layer EML configured to emit light in response to electrical signal, and may further include a Hole Injection Layer HIL and a Hole Transport Layer HTL disposed between the emission layer EML and the pixel electrode 210, and an Electron Transport Layer ETL and an Electron Injection Layer EIL disposed between the emission layer EML and the counter electrode 230. The counter electrode 230 may be formed to cover the whole area of the flexible substrate 100.

A thickness of the thin film transistor TFT, the OLED 240, and the encapsulating layer 350 disposed on the flexible substrate 100 may be between 20 μm and 30 μm. Since, the total thickness of a display panel including the flexible substrate 100 may be thin, which is between 30 μm and 40 μm, to maintain the strength and preserve the flexibility, the exemplary embodiments may include a protection substrate attached to the lower surface of the flexible substrate 100.

According to the exemplary embodiment, a integrated sensor 400 including the EMR sensor and the pressure sensor on the lower surface of the flexible substrate 100, wherein the plurality of pixels 112 is disposed on an upper surface of the flexible substrate 100. More specifically, the integrated sensor 400 is integrally disposed on the protection substrate, directly onto the lower surface of the flexible substrate 100.

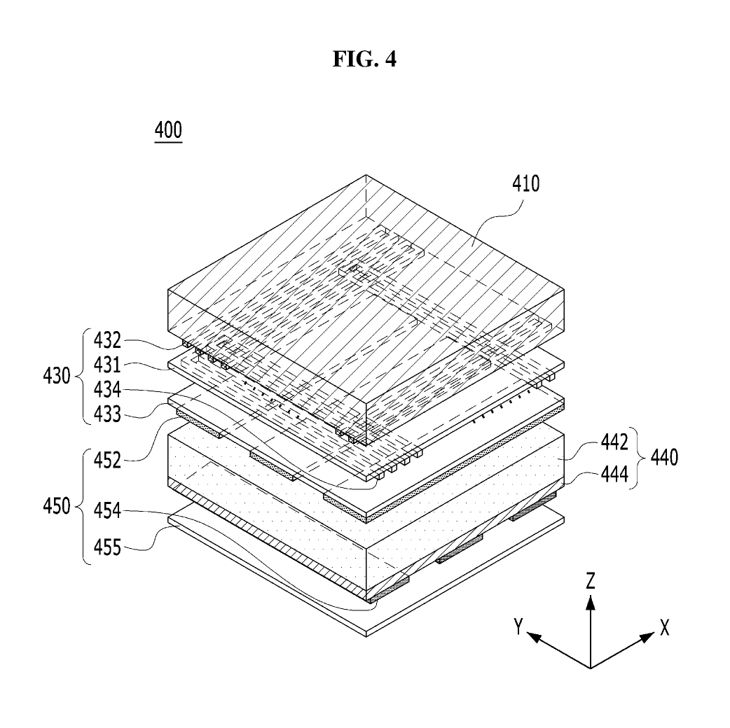

The integrated sensor 400 may have a stacked structure include the first loop coils and the second loop coils of the EMR sensor and the first electrodes and the second electrodes of the pressure sensor stacked together, and the integrated sensor 400 will be further described with reference to FIG. 4.

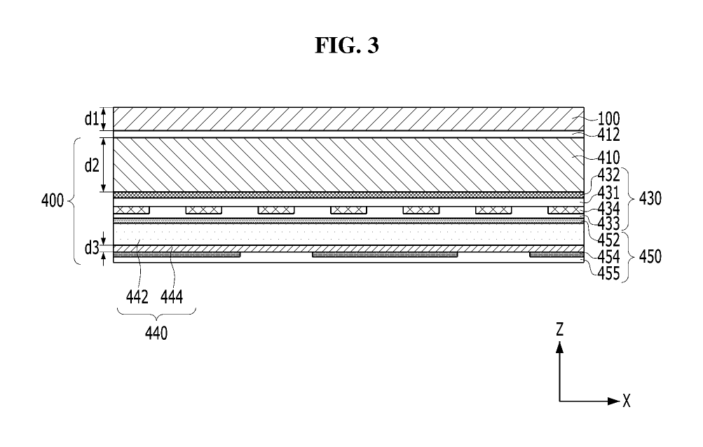

FIG. 3 is a cross-sectional drawing illustrating a stacked structure of the integrated sensor 400 constructed according to the principles of the invention, and FIG. 4 is an exploded perspective drawing illustrating the stacked structure of a integrated sensor 400 of FIG. 3 constructed according to an exemplary embodiment of the invention.

Referring to FIG. 3, the integrated sensor 400 according to the exemplary embodiments includes sensing patterns disposed on the lower surface of the flexible substrate 100.

According to the exemplary embodiment of FIG. 3 illustrates that an adhesive, e.g., Optically Clear Adhesive OCA 412, may be disposed between the flexible substrate 100 and the support substrate 410 to adhere the flexible substrate 100 and the support substrate 410 together, but the exemplary embodiments are not limited thereto. For example, the flexible substrate 100 and the support substrate 410 may be formed of a single substrate without being adhered with the adhesive 412.

The support substrate 410 may be flexible, and may have a second thickness d₂. For example, the second thickens d₂ of the protection substrate 410 may be between 90 μm and 110 μm, more particularly, substantially 100 μm.

Accordingly, the support substrate 410 having the second thickness d₂ which may provide strength and preserve flexibility may be attached to the flexible substrate 100, and the plurality of pixels 112 disposed on the flexible substrate 100 may be protected from deterioration from environmental factors such as external force.

Considering the elements disposed on the display panel, e.g., polarization panel, window, etc., the support substrate 410 attached to the lower surface of the flexible substrate 100 may lower a neutral plane of stress caused by bending the flexible substrate 100 in a vertical direction (Z axis direction) may be formed in the same layer that the plurality of pixels 112 are disposed.

The support substrate 410 may include plastic materials including PET, PEN, PI, etc. For descriptive purpose, the support substrate 410 includes polyimide PI, but the exemplary embodiments are not limited thereto.

Referring to FIG. 3 and FIG. 4, the integrated sensor 400 according to the exemplary embodiment may include a stacked structure including the EMR sensor 430 and the pressure sensor 450 stacked. The EMR sensor 430 may include the first loop coils 432 disposed in a first direction (X axis direction) and the second loop coils 434 disposed in a second direction (Y axis direction), and the pressure sensor 450 may include the first electrodes 452 disposed in the first direction (X axis direction) and the second electrodes 454 disposed in the second direction (Y axis direction).

Referring to FIG. 3 and FIG. 4, the first loop coils 432 and the second loop coils 434 of the EMR sensor 430 and the first electrodes 452 of the pressure sensor 450 may be sequentially stacked on the lower surface of the support substrate 410.

The second electrodes 454 of the pressure sensor 450 may be disposed on a surface of an elastic substrate 440, and the elastic substrate is attached to the support substrate 410.

The elastic substrate 440 may include an elastic layer 442 and a base substrate 444. The elastic layer 442 may have any shape and include any material that may elastically restore a gap between the first electrodes 452 and the second electrodes 454 of the pressure sensor 450. For example, the elastic layer 442 may include elastic material including polyolefin, PVC, polystyrene, polyurethane, polyamide, etc., and may also include silicon rubber. Also, the elastic layer 442 may be a foam tape, which may provide an adhesive surface to attach the elastic substrate onto the support substrate 410.

The base substrate 444 may have flexibility, and the base substrate may have a third thickness d₃. For example, the third thickens d₂ of the base substrate 444 may be between 5 μm and 15 μm, more particularly, substantially 10 μm. The protection substrate 444 may include plastic materials including PET, PEN, PI, etc. For descriptive purpose, the base substrate 444 includes polyimide PI, but the exemplary embodiments are not limited thereto.

Accordingly, the integrated sensor 400 according to the exemplary embodiment includes the support substrate 410 and the elastic substrate 440, and sensing patterns of EMR sensor 430 including the first loop coils 432 and the second loop coils 434, and a part of sensing patterns of the pressure sensor 450 including the first electrodes 452 of the pressure sensor 450 are disposed on the support substrate 410. The second electrodes 454 of the pressure sensor 450, which is the rest of the sensing patterns of the pressure sensor 450, are disposed on the elastic substrate 440.

The integrated sensor 400 according to the exemplary embodiment includes the support substrate 410, on which multiple sensors including the EMR sensor 430 and a part of the pressure sensor 450 are sequentially stacked, and the elastic substrate 440, on which the rest of the pressure sensor 450 are disposed.

More specifically, referring to FIG. 3 and FIG. 4, the first loop coils 432 are disposed in the first direction on the lower surface of the protection layer 410, and a first lower insulating layer 432 is disposed on the first loop coils 432. The second loop coils 434 are disposed on the first lower insulating layer 431 in the second direction which crosses the first direction. In other words, the first loop coils 432 and the second loop coils 434 are disposed to cross each other, but the first lower insulating layer 431 may electrically insulate the first loop coils 432 and the second loop coils 434.

The first loop coils 432 and the second loop coils 434 may include metal including copper Cu, aluminum Al, molybdenum Mo, silver Ag. The EMR sensor 430 is disposed under the plurality of pixels 112, and do not affect transmissivity of the display panel. Therefore, the first loop coils 432 and the second loop coils 434 are not restricted to any line width, thickness, and location limits, and may be openly designed according to the low resistance required by the EMR method.

The integrated sensor 400 according to the exemplary embodiment may have the first electrodes 452 and the second electrodes 454 of the pressure sensor 450 may be disposed on different substrates. The pressure sensor 450 according to the exemplary embodiment may include transmitting electrodes to which a scan signal is sequentially applied, and receiving electrodes configured to detect sensing signal in response to pressure applied to the sensor. The sensing signal detected by the receiving electrodes may be interfered by other signals, but the scan signal is relatively less affected by the other signals.

Referring to FIG. 3 and FIG. 4, the first electrodes 452 of the pressure sensor 450 is disposed on a lower surface of the EMR sensor 430 stacked on the support substrate 410.

A second lower insulating layer 433 is disposed on the second loop coils 434 of the EMR sensor 430, which is disposed on the lower surface of the support substrate 410, and the first electrodes 452 of the pressure sensor 450 is disposed in the first direction on a lower surface of the second lower insulating layer 433. The first electrodes 452 may function as the transmitting electrodes of the pressure sensor 450, to which the scan signal is sequentially applied. The EMR sensor 430 is disposed on the support substrate 410, so the first electrodes 452 are disposed adjacent to the EMR sensor 430. However, the first electrodes 452 functions as transmitting electrode, and therefore, may relatively be less affected by the EMR sensor 430, and operation of the pressure sensor 450 is relatively less affected by the EMR sensor 430.

The second electrodes 454 of the pressure sensor 450 may be disposed on a lower surface of the elastic substrate 440.

More specifically, the elastic layer 442 of the elastic substrate 440 is disposed on a lower surface of the first electrodes 452, and the second electrodes 454 of the pressure sensor 450 may be disposed on a lower surface of the base substrate 444 of the elastic substrate 440. A third lower insulating layer 455 may be disposed on the second electrodes 454 to encapsulate the second electrode 454 from the external environment.

The second electrodes 454 is disposed in the second direction which crosses the first decision, and may function as the receiving electrodes.

The first electrodes 452 and the second electrodes 454 may include metal including copper Cu, aluminum Al, molybdenum Mo, silver Ag. The pressure sensor 450 is disposed under the plurality of pixels 112, and do not affect the transmissivity of the display panel. Therefore, the first electrodes 452 and the second electrodes 454 are not restricted to any line width, thickness, and location limits, and may be openly designed according to the low resistance required by the pressure sensing method

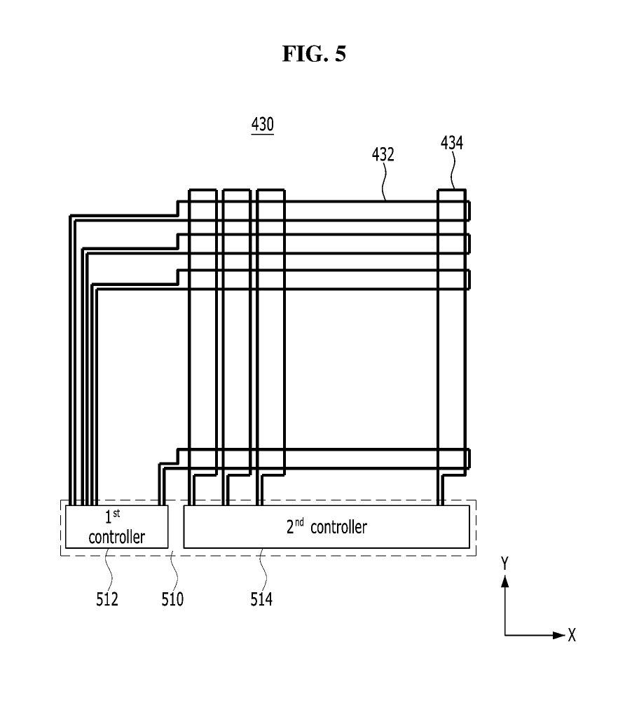

FIG. 5 is a plan view of an exemplary embodiment of the EMR sensor 430 of the integrated sensor 400 of FIG. 4.

Referring to FIG. 5, the first loop coils 432 of the EMR sensor 430 may include a plurality of first loop coils disposed in the first direction (the X axis direction) at a predetermined distance, where each of the plurality of first loop coils have one open terminal. The open terminal of the plurality of first loop coils may be electrically connected to a first EMR controller 512 through the sensing pad (FIG. 1, 119). The first EMR controller 512 is included in an EMR sensing IC 510, which is included in the FPCB (FIG. 1, 300).

The second loop coils 432 of the EMR sensor 430 may include a plurality of second loop coils disposed in the second direction (the Y axis direction) at a predetermined distance, where each of the plurality of second loop coils have one open terminal. The open terminal of the plurality of second loop coils may be electrically connected to a second EMR controller 514 through the sensing pad (FIG. 1, 119). The second EMR controller 514 is included in an EMR sensing IC 510, which is included in the FPCB (FIG. 1, 300).

For example, At least one of the first loop coils 432 and the second loop coils 434 may function as driving channel configured to generated electromagnetic field, and the other may be a detecting channel configured to detect the location of a stylus pen. Both of the first loop coils 432 and the second loop coils 434 may function as detecting channel configured to detect the location of a stylus pen. The exemplary embodiment of FIG. 5 illustrates that both the first loop coils 432 and the second loop coils 434 function as detecting channel for descriptive purpose, and the exemplary embodiments are not necessarily limited thereto.

When the stylus pen touches the display panel, a predetermined voltage level may be selectively applied to one first loop coil of the first loop coils 432 and one second loop coil of the second loop coils 434 that are closest to a touch area that the stylus pen touched. A passive operation of the EMR sensor 430 is described as follows.

The first and second EMR controllers 512 and 514 of the EMR sensing IC 510 are configured to apply EMR signal to the EMR sensor 430, and the first and second EMR controllers 512 and 514 of the EMR sensing IC 510 may selectively apply the EMR signal to the first loop coils 432 and the second loop coils 434 to generate electromagnetic field by electromagnetism.

The passive stylus pen including a resonance circuit may store a resonance frequency from the generated electromagnetic field, and the EMR sensor 430 may receive the stored resonance frequency to detect the touch area of the stylus pen.

The passive stylus pen includes a LC resonance circuit that may show maximum current at certain frequency corresponding to the resonance voltage, and therefore, the LE resonance circuit may detect the output characteristic at the certain frequency correspond to the resonance voltage.

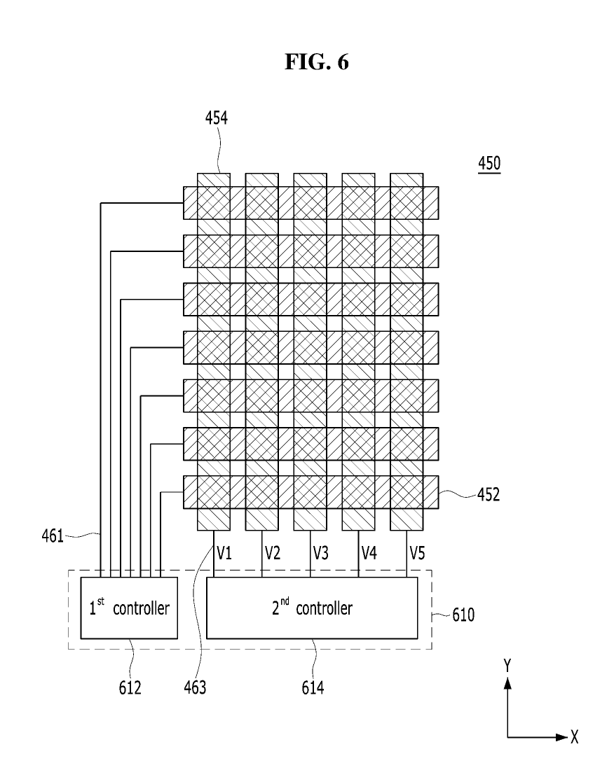

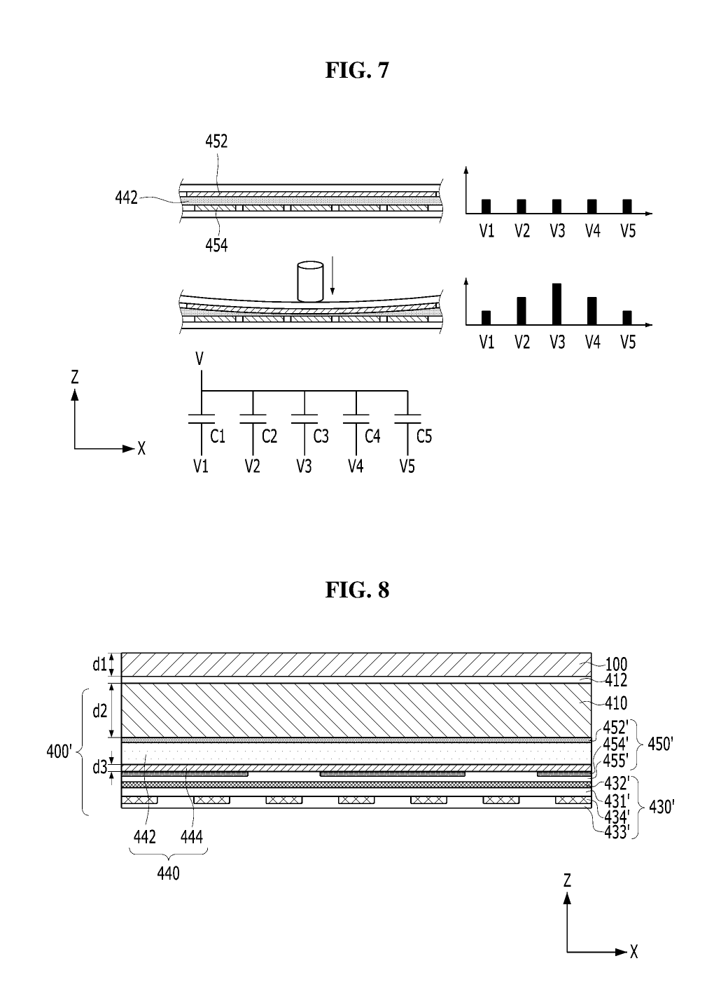

FIG. 6 is a plan view of an exemplary embodiment of the pressure sensor 450 of the integrated sensor 400 of FIG. 4, and FIG. 7 illustrates an exemplary operation of the pressure sensor 450 of FIG. 6, according to an exemplary embodiment.

Referring to FIG. 6, the first electrodes 452 of the pressure sensor 450 may include a plurality of first electrodes disposed in the first direction (the X axis direction) at a predetermined distance. Each of the plurality of first electrodes of the first electrodes 452 may be electrically connected to a first pressure sensor controller 612 through the sensing pad (FIG. 1, 119). The first pressure sensor controller 612 is included in a pressure sensor sensing IC 610, which is included in the FPCB (FIG. 1, 300).

The second electrodes 454 of the pressure sensor 450 may include a plurality of second electrodes disposed in the second direction (the Y axis direction) at a predetermined distance. Each of the plurality of second electrodes of the second electrodes 454 may be electrically connected to a second pressure sensor controller 614 through the sensing pad (FIG. 1, 119). The second pressure sensor controller 614 is included in an pressure sensor sensing IC 610, which is included in the FPCB (FIG. 1, 300).

For descriptive purpose, FIG. 6 and FIG. 7 illustrated that the pressure sensor 450 includes 6 first electrodes and 5 second electrodes, but the exemplary embodiments are not limited thereto.

The elastic substrate (FIGS. 3 and, 440) is disposed between the first electrode 452 and the second electrodes 454. The elastic substrate 440 may include the elastic layer 442 having elasticity to restore the gap between the first electrodes 452 and the second electrodes 454, when gap between the first electrodes 452 and the second electrodes 454 may be changed due to external touch and pressure to change the capacitance formed between the first electrodes 452 and the second electrodes 454.

Referring to FIG. 7, a predetermined voltage V is applied to the first electrodes 452 and the second electrodes 454 of the pressure sensor 450, and when the external pressure is applied to a pressure point, the gap between the first electrodes 452 and the second electrodes 454 disposed in the pressure point is changed, which in turn changes the capacitance in the pressure point (C1, C2, C3, C4, and C5) changes. The change in the capacitance may change corresponding output voltages of the second electrodes 454 (V1, V2, V3, V4, and V5), and the pressure point may be detected by detecting the change in the output voltages of the second electrodes 454.

FIG. 8 is a cross-sectional drawing illustrating a stacked structure of a integrated sensor 400′, according to another exemplary embodiment.

Compared to the integrated sensor 400 illustrated in FIG. 3, the integrated sensor 400′ illustrated in FIG. 8 includes different stacking structure of the sensing patterns disposed on the support substrate 410 and the elastic substrate 440. Accordingly, same reference numerals are used for the integrated sensor 400′ in FIG. 8 to denote same elements of the integrated sensor 400 of FIG. 3.

Referring to FIG. 8, the integrated sensor 400′ according to the exemplary embodiment includes the support substrate 410 and an elastic substrate 440, disposed on the lower surface of the flexible substrate 100, a part of sensing patterns of the pressure sensor 450′ including the first electrodes 452′ of the pressure sensor 450′ are disposed on the support substrate 410. On the other hand, the rest of the sensing patterns of the pressure sensor 450′ including the second electrodes 454′ of the pressure sensor 450′ and the sensing patterns of EMR sensor 430′ including the first loop coils 432′ and the second loop coils 434′ are disposed on the elastic substrate 440.

The integrated sensor 400′ according to the exemplary embodiment, the pressure sensor 450′ and the sensing patterns of EMR sensor 430′ including the first loop coils 432′ and the second loop coils 434′ are sequentially stacked on the elastic substrate 440, and the rest of the sensing patterns of the pressure sensor 450′ including the second electrodes 454′ of the pressure sensor 450′ is disposed on the support substrate 410.

The integrated sensor 400′ according to the exemplary embodiment may have the first electrodes 452′ and the second electrodes 454′ of the pressure sensor 450′ may be disposed on different substrates.

More specifically, referring to FIG. 8, the first electrodes 452′ of the pressure sensor 450′ are disposed on a lower surface of the support substrate 410 in the first direction. The first electrodes 452′ may function as receiving electrodes configured to detect sensing signal.

The elastic layer 442 is disposed under the first electrodes 452′, and the second electrodes 454′ of the pressure sensor 450′ may be formed on the lower surface of the base substrate 444 of the elastic substrate 440 may function as the transmitting electrodes of the pressure sensor 450′, to which the scan signal is sequentially applied. The first lower insulating layer 432′ is disposed on the lower surface of the base substrate 444, on which the second electrodes 454′ are disposed.

The first loop coils 432′ are disposed on the lower surface of the first lower insulating layer 432′ in the first direction, and the second lower insulating layer 431′ is disposed on the lower surface of the base substrate 444 including the first loop coils 432′. The second loop coils 434′ is disposed on the second lower insulating layer 431′ in the second direction which crosses the first direction. In other words, the first loop coils 432′ and the second loop coils 434′ are disposed to cross each other, but the first lower insulating layer 431′ may electrically insulate the first loop coils 432′ and the second loop coils 434′.

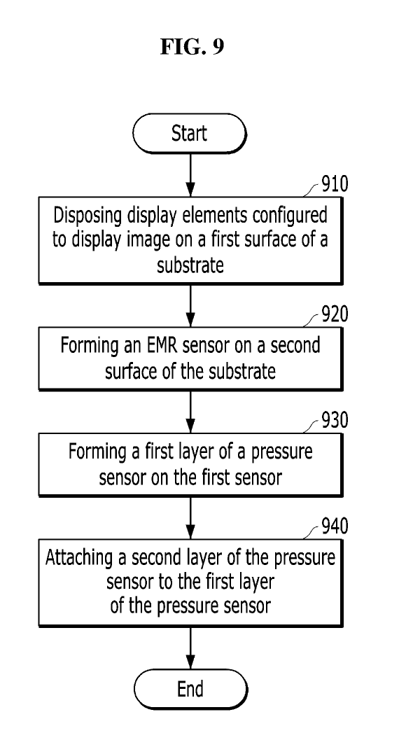

FIG. 9 is a flow chart schematically depicting some of the steps of an exemplary method of manufacturing a flexible display device including the integrated sensor 400 constructed according to an exemplary embodiment of the invention.

Referring to FIG. 9, the flexible display device may include display elements, and the integrated sensor 400 may include the EMR sensor and the pressure sensor. The detailed descriptions of the EMR sensor and the pressure sensor may be substantially identical to FIGS. 5 and 6, and therefore, are omitted.

First, the display elements configured to display image may be disposed on a first surface of a substrate (910). The display elements may include the liquid crystal display (LCD) elements and organic light emitting diode (OLED) display elements. The substrate may be a flexible substrate. The flexible substrate may comprise a flexible substrate and a support substrate. The support substrate may have a first surface and a second surface, and the flexible substrate may have a first surface and a second surface. The flexible substrate may be disposed between the support substrate and the display elements. The first surface of the substrate may be the first surface of the flexible substrate, and the second surface of the substrate may be the second surface of the support substrate.

The EMR sensor may be formed on a second surface of the substrate (920). The EMR sensor may be formed onto the second surface of the support substrate, and the first surface of the support substrate may be attached onto the second surface of the flexible substrate.

Thereafter, a first layer of the pressure sensor may be formed on the first sensor (930), and a second layer of the pressure sensor may be attached to the first layer of the pressure sensor (940). The second layer of the pressure sensor may include a second electrode layer and an elastic substrate including a base substrate and elastic layer. The elastic layer may be disposed on a first surface of the base substrate, and the second electrode may be disposed on a second surface of the base substrate. The second layer of the pressure sensor may be attached to the first layer of the pressure sensor by attaching the elastic layer onto the first layer of the pressure sensor. The elastic layer may be a foam tape or other means known in the art.

The flexible display device according to exemplary embodiments of the invention may include an integrated sensor 400 incorporated into the flexible display device 10, where the integrated sensor 400 may be configured to detect touch from both the stylus pen and the finger pressure of the user. Accordingly the total thickness of the display device may be reduced, and the flexible display device may have improved flexibility. The integrated sensor according to the exemplary embodiments may have a structure that minimizes the use of adhesive layers to reduce the overall thickness of the display, and make the flexible display device more stress resistant.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. A display device comprising:
a substrate having a first and second sides;
display elements disposed on the first side of the substrate configured to display image;
a first sensor disposed on the second side of the substrate to sense a first input; and
a second sensor disposed on the first sensor to sense a second input, the second sensor having a layer integrated with the first sensor.

2. The display device of claim 1, wherein the substrate comprises:
a support substrate; and
a flexible substrate disposed between the support substrate and the display elements.

3. The display device of claim 1, wherein the second sensor is configured to detect changes in an external condition of the display device.

4. The display device of claim 3, wherein the external condition is a pressure applied to the display device.

5. The display device of claim 4, wherein the layer of the second sensor comprises a first electrode layer, and
wherein the second sensor further comprises:
a second electrode layer; and
an elastic substrate disposed between the first electrode layer and the second electrode layer.

6. The display device of claim 5, wherein the first electrode layer is a transmitting electrode configure to transmit scan signals.

7. The display device of claim 6, wherein the second electrode layer of the second sensor is configured detect a location of the applied pressure by detecting the change of capacitance in response to the change of the gap between the first electrode layer and the second electrode layer.

8. The display device of claim 2, wherein the first sensor is integrated with the support substrate.

9. The display device of claim 1, wherein the first input is a location of an input device.

10. The display device of claim 9, wherein the first sensor is an electromagnetic resonance (EMR) sensor.

11. The display device of claim 10, wherein the input device comprises a resonance circuit to generate a resonance frequency signal in response to an electromagnetic field generated by the EMR sensor, and
wherein the EMR sensor detects the location of the input device by detecting the resonance frequency signal.

12. A display device comprising:
a substrate having first and second sides;
display elements disposed on the first side of the substrate configured to display image;
an electromagnetic resonance (EMR) sensor disposed on the second side of the substrate; and
a pressure sensor disposed on the EMR sensor, the pressure sensor including a first electrode layer integrated with the EMR sensor.

13. The display device of claim 12, wherein the substrate comprises:
a support substrate; and
a flexible substrate disposed between the support substrate and the display elements.

14. The display device of claim 13, wherein the pressure sensor further comprises a second electrode layer and an elastic substrate disposed between the first electrode layer and the second electrode layer.

15. The display device of claim 14, wherein the elastic substrate comprises a base substrate and an elastic layer.

16. The display device of claim 15, wherein the elastic layer comprises an adhesive surface and the adhesive surface of the elastic layer is directly attached to the first electrode layer.

17. The display device of claim 16, wherein the flexible substrate, the support substrate, and the base substrates are made of substantially the same material.

18. The display device of claim 17, wherein the flexible substrate, the support substrate, and the base substrates each comprise polyimide material.

19. The display device of claim 18, wherein the first electrode layer is a transmitting electrode configured to transmit scan signals, and
wherein the second electrode layer of the pressure sensor is configured to detect the change of capacitance in response to the change in the size of the gap between the first electrode layer and the second electrode layer is configured to detect a location of a pressure applied to the display device.

20. A method of manufacturing a flexible display device having multiple sensors comprising:
disposing display elements configured to display image on a first surface of a substrate;
forming a first sensor on a second surface of the substrate;
forming a first layer of a pressure sensor on the first sensor; and
attaching a second layer of the pressure sensor to the first layer of the pressure sensor.

21. The method of claim 20, wherein the substrate comprises:
a support substrate having a first surface and a second surface;
a flexible substrate having a first surface and a second surface, the flexible substrate being disposed between the support substrate and the display elements,
wherein the first surface of the substrate is the first surface of the flexible substrate, and
wherein the second surface of the substrate is the second surface of the support substrate.

22. The method of claim 21, wherein the forming the first sensor comprises:
forming a first layer of the first sensor directly on the second surface of the support substrate; and
attaching the first surface of the support substrate to the second surface of the flexible substrate.

23. The method of claim 20, wherein the forming the first layer of the pressure sensor comprises:
forming a first electrode layer directly on the first sensor.

24. The method of claim 20, wherein the attaching the second layer of the pressure sensor comprises:
forming a second electrode layer on an elastic substrate, the elastic substrate including an elastic layer disposed on a first surface of a base substrate;
and attaching the elastic substrate to the first layer of the pressure sensor.

25. The method of claim 24, wherein the second electrode layer is disposed on a second surface of the base substrate and the elastic layer is disposed on a first surface of the base substrate.

26. An integrated sensor in a display device comprising:
a first sensor to detect a first condition of the display device;
a second sensor to detect a second condition of the display device, and
wherein the first sensor and the second sensor are integrated without adhesive.

27. The integrated sensor of claim 26, wherein a layer of the second sensor is formed directly on the first sensor.

28. The integrated sensor of claim 26, wherein the second condition of the display device is the amount of pressure applied to the display device.

29. The integrated sensor of claim 27, wherein the layer of the second sensor comprises a first electrode layer, and
wherein the second sensor further comprises:
a second electrode layer; and
an elastic substrate disposed between the first electrode layer and the second electrode layer.

30. The integrated sensor of claim 29, wherein the first electrode layer is a transmitting electrode configure to transmit scan signals, and
wherein the second electrode layer of the second sensor is configured detect a location of the applied pressure by detecting the change of capacitance in response to the change in the size of a gap between the first electrode layer and the second electrode layer.

31. The integrated sensor of claim 26, wherein the first sensor is directly formed on the display device without any intervening layers.

32. The integrated sensor of claim 26, the first condition is a location of an input device.

33. The integrated sensor of claim 32, wherein the first sensor is an electromagnetic resonance (EMR) sensor.

34. The integrated sensor of claim 33, wherein the EMR sensor is configured to generate an electromagnetic field and detect the location of the input device by detecting a resonance frequency signal generated by the input device in response to the electromagnetic field generated by the EMR sensor.
